(19) United States
(12) Patent Application Publication
(10) Pub. No.: US 2025/0362328 A1
(43) Pub. Date: Nov. 27, 2025

(54) ELECTRIC METER, EDGE SERVER, CLOUD SERVER, AND SYSTEM FOR ELECTRIC POWER DATA ANALYSIS

(71) Applicant: The University of Hong Kong Shenzhen Institute of Research and Innovation, Shenzhen (CN)

(72) Inventors: Yi WANG, Hong Kong (HK); Yehui LI, Hong Kong (HK); Dalin QIN, Hong Kong (HK)

(21) Appl. No.: 19/215,396

(22) Filed: May 22, 2025

(30) Foreign Application Priority Data
May 24, 2024 (CN) 202410652152.3

(51) Int. Cl. G01R 21/133; G06N 3/084

(52) U.S. Cl. CPC G01R 21/133; G06N 3/084

(57) ABSTRACT

An electric meter, an edge server, and a system for electric power data analysis are disclosed. The electric meter includes an electric power data acquisition device for collecting electric power data; a memory for storing a first part of an electric power data analysis model; and a processor for training the first part, including: using the first part to process electric power data to generate a first representation of the electric power data; sending the first representation to an edge server; receiving a second representation of the electric power data generated by processing the first representation; using the first part to process the second representation to generate a first electric power data analysis result; using the first electric power data analysis result to perform backward propagation on the first part to generate an updated first part and a gradient of the second representation.

### TECHNICAL FIELD

The present invention relates to an electric power system, and in particular to an electric meter, an edge server, a cloud server, and a system for electric power data analysis.

### BACKGROUND

The power system accounts for more than 40% of global CO₂ emissions. Adopting a high proportion of renewable energy is an important way to achieve the low-carbon transformation of the power system and thus mitigate climate change. Exploring the flexibility of the demand side offers a viable approach to mitigating the uncertainty associated with the introduction of renewable energy sources, thereby promoting the use of renewable energy. It is estimated that, by 2028, the number of smart electric meters worldwide will exceed 1.2 billion, with a penetration rate of more than 59%. This ubiquity of smart electric meters will make it possible for them to become a core feature of future smart electric grids, as they can support demand-side flexibility by collecting a large amount of fine-grained electricity consumption data. However, current smart electric meters are still not smart enough. They cannot perform on-device intelligent data analysis and instead transmit the collected data in bulk to centralized data management systems, which may cause problems such as user privacy leakage, data transmission congestion, and decision response delays.

Without introducing any additional facility investment, empowering existing ubiquitous smart electric meters with edge intelligent analysis capabilities offers a cost-effective approach to enabling more autonomous and efficient management of flexible resource. Furthermore, making smart electric meters intelligent can reduce the need for local data upload, thereby alleviating users' concerns about data privacy and increasing consumers' willingness to adopt smart electric meters. However, due to the limitations of data availability and hardware resources, existing data analysis methods are not applicable to large-scale deployments of smart electric meters for the following reasons: 1) Smart electric meter data involves user privacy, which hinders the use of distributed data to improve model performance; 2) The memory, computing and communication resources of smart electric meters are insufficient to support complex model training.

### SUMMARY OF INVENTION

In the present disclosure, an electric meter is provided. The electric meter includes an electric power data acquisition device, a memory, a communication device, and a processor. The electric power data acquisition device is configured to collect electric power data. The memory is configured to store a first part of an electric power data analysis model. The processor is coupled to the electric power data acquisition device, the memory and the communication device and is configured to train the first part of the electric power data analysis model. The training the first part of the electric power data analysis model comprises: processing the electric power data using the first part of the electric power data analysis model to generate a first representation of the electric power data; sending the first representation of the electric power data to an edge server via the communication device; receiving, from the edge server via the communication device, a second representation of the electric power data generated by the edge server by processing the first representation of the electric power data; processing the second representation of the electric power data using the first part of the electric power data analysis model to generate a first electric power data analysis result; performing backward propagation on the first part of the electric power data analysis model using the first electric power data analysis result to generate an updated first part of the electric power data analysis model and a gradient of the second representation of the electric power data; and sending the gradient of the second representation to the edge server via the communication device.

According to one embodiment of the present disclosure, the second representation of the electric power data is generated by the edge server by processing the first representation of the electric power data using a second part of the electric power data analysis model.

According to one embodiment of the present disclosure, the first part of the electric data analysis model comprises a feature extractor and a regressor. The processing the electric data using the first part of the electric data analysis model to generate the first representation of the electric data comprises processing the electric data using the feature extractor to generate the first representation of the electric data. The processing the second representation of the electric data using the first part of the electric data analysis model to generate the first electric data analysis result comprises processing the second representation of the electric data using the regressor to generate the first electric data analysis result.

According to one embodiment of the present disclosure, the performing backward propagation on the first part of the electric data analysis model using the first electric data analysis result comprises performing backward propagation on the regressor based on a first loss between the first electric data analysis result and a true value.

According to one embodiment of the present disclosure, the memory is further configured to store an auxiliary regressor of the electric data analysis model. The auxiliary regressor is configured to process the first representation of the electric data to generate a second electric data analysis result.

According to one embodiment of the present disclosure, the processor is further configured to integrate the first electric data analysis result with the second electric data analysis result.

According to one embodiment of the present disclosure, the processor is further configured to: output the first electric power data analysis result when a communication capability is higher than a threshold value; and output the second electric power data analysis result when the communication capability is lower than the threshold value.

According to one embodiment of the present disclosure, the processor is further configured to perform backward propagation on the feature extractor based on a second loss between the second electric power data analysis result and the true value.

According to one embodiment of the present disclosure, performing backward propagation on the feature extractor further comprises performing backward propagation on the feature extractor based on the second loss and a knowledge distillation loss between the first electric power data analysis result and the second electric power data analysis result.

According to one embodiment of the present disclosure, the gradient of the second representation is introduced to perform backward propagation on the second part of the electric power data analysis model. The backward propagation performed on the first part of the electric power data analysis model is performed in parallel with the backward propagation performed on the second part of the electric power data analysis model.

According to one embodiment of the present disclosure, a ratio of the size of the first part of the electric power data analysis model to the size of the electric power data analysis model is determined based on time consumed to train the electric power data analysis model.

According to one embodiment of the present disclosure, the time consumed for training the electric data analysis model comprises time for performing forward propagation and backward propagation on the electric data analysis model and time for the processor to communicate with the edge server via the communication device.

According to one embodiment of the present disclosure, the time for performing forward propagation and backward propagation on the electric data analysis model comprises a sum of the maximum values of time for performing forward propagation on the first part of the electric data analysis model in the electric meter, time for performing forward propagation on the second part of the electric data analysis model in the edge server, time for performing backward propagation on the first part of the electric data analysis model in the electric meter, and time for performing backward propagation on the second part of the electric data analysis model in the edge server.

According to one embodiment of the present disclosure, the time for the processor to communicate with the edge server via the communication device comprises a sum of items as follows: time for the processor to send the first representation of the electric power data to the edge server via the communication device; time for the processor to receive the second representation of the electric power data from the edge server via the communication device; time for the processor to send the gradient of the second representation of the electric power data to the edge server via the communication device; time for the processor to receive the first part of the electric power data analysis model from the edge server via the communication device; and time for the processor to send the updated first part of the electric power data analysis model to the edge server via the communication device.

According to one embodiment of the present disclosure, a lower bound of the size of the first part of the electric power data analysis model is greater than or equal to the size of an input layer and an output layer of the electric power data analysis model. An upper bound of the size of the first part of the electric power data analysis model is less than or equal to that an available storage capacity of the memory of the electric meter minus the size of an intermediate memory of the first part of the electric power data analysis model and the size of an optimizer memory of the first part of the electric power data analysis model.

According to one embodiment of the present disclosure, a ratio of the size of the first part of the electric data analysis model to the size of the electric data analysis model is determined based on the lower bound and the upper bound of the size of the first part of the electric data analysis model, such that time consumed in training the electric data analysis model is minimized.

According to one embodiment of the present disclosure, the processor is further configured to send the updated first part of the electric data analysis model to the edge server via the communication device.

According to one embodiment of the present disclosure, the processor is further configured to receive the first part of the electric data analysis model from the edge server via the communication device and store the first part of the electric data analysis model in the memory.

According to one embodiment of the present disclosure, the electric meter

and one or more other electric meters are clustered into an electric meter set based on a computational capability and a communication rate of the electric meter. The electric meters in the electric meter set correspond to a first edge server.

According to one embodiment of the present disclosure, the first part of the electric data analysis model received from the first edge server via the communication device is a first part of a synchronously aggregated electric data analysis model. The first part of the synchronously aggregated electric data analysis model is generated by the first edge server by synchronously aggregating the first part of the electric data analysis model in the electric meter set.

According to one embodiment of the present disclosure, the first part of the electric data analysis model received from the first edge server via the communication device is a first part of an asynchronously aggregated electric data analysis model. The first part of the asynchronously aggregated electric data analysis model is received by the first edge server from the cloud server. The first part of the asynchronously aggregated electric data analysis model is generated by the cloud server by asynchronously aggregating the electric data analysis model sent by the first edge server and one or more other edge servers.

In the present disclosure, an edge server is provided. The edge server includes a memory, a communication device, and a processor. The memory is configured to store a second part of an electric power data analysis model. The processor is coupled to the memory and the communication device and is configured to train the second part of the electric power data analysis model. The training the second part of the electric power data analysis model comprises: receiving a first representation of electric power data from an electric meter via the communication device; processing the first representation of the electric power data using the second part of the electric power data analysis model to generate a second representation of the electric power data; sending the second representation of the electric power data to the electric meter via the communication device; receiving a gradient of the second representation from the electric meter via the communication device;

performing backward propagation on the second part of the electric power data analysis model using the gradient of the second representation to generate an updated second part of the electric power data analysis model.

In the present disclosure, a system for electric power data analysis is provided. The system includes one or more electric meters, one or more edge servers, and a cloud server. The one or more electric meters are clustered into one or more electric meter sets based on computational capabilities and communication rates of the electric meters. Each of the one or more edge servers corresponds to one of the one or more electric meter sets. The cloud server corresponds to the one or more edge servers. The one or more electric meters are configured to train a first part of an electric power data analysis model, wherein training the first part of the electric power data analysis model comprises: processing electric power data using the first part of the electric power data analysis model to generate a first representation of the electric power data; sending the first representation of the electric power data to the edge server via a communication device; receiving, from the edge server via the communication device, a second representation of the electric power data generated by the edge server by processing the first representation of the electric power data; processing the second representation of the electric power data using the first part of the electric power data analysis model to generate a first electric power data analysis result; performing backward propagation on the first part of the electric power data analysis model using the first electric power data analysis result to generate an updated first part of the electric power data analysis model and a gradient of the second representation of the electric power data; sending the gradient of the second representation to the edge server via the communication device. An edge server in the one or more edge servers is configured to train a second part of the electric power data analysis model, and training the second part of the electric power data analysis model comprises: receiving the first representation of the electric power data from the electric meter via the communication device; processing the first representation of the electric power data using the second part of the electric power data analysis model to generate the second representation of the electric power data; sending the second representation of the electric power data to the electric meter via the communication device, receiving the gradient of the second representation from the electric meter via the communication device; using the gradient of the second representation to perform backward propagation on the second part of the electric power data analysis model to generate an updated second part of the electric power data analysis model. An edge server in the one or more edge servers synchronously aggregates the electric power data analysis model corresponding to the edge server. The cloud server asynchronously aggregates the electric power data analysis model in the one or more edge servers corresponding to the cloud server.

In the present disclosure, a method performed by an electric meter is provided, including training a first part of an electric data analysis model. The training includes: processing electric data using the first part of the electric data analysis model to generate a first representation of the electric data; sending the first representation of the electric data to an edge server via a communication device; receiving a second representation of the electric data generated by the edge server by processing the first representation of the electric data from the edge server via the communication device; processing the second representation of the electric data using the first part of the electric data analysis model to generate a first electric data analysis result; performing backward propagation on the first part of the electric data analysis model using the first electric data analysis result to generate an updated first part of the electric data analysis model and a gradient of the second representation of the electric data; and sending the gradient of the second representation to the edge server via the communication device.

In the present disclosure, a method performed by an edge server is provided, including: receiving a first representation of electric data from an electric meter via a communication device; processing the first representation of the electric data using a second part of the electric data analysis model to generate a second representation of the electric data; sending the second representation of the electric data to the electric meter via the communication device; receiving a gradient of the second representation from the electric meter via the communication device; and performing backward propagation on the second part of the electric data analysis model using the gradient of the second representation to generate an updated second part of the electric data analysis model.

The electric meter, the edge server, the cloud server, and the system for electric power data analysis according to the present disclosure are advantageous for improving the management efficiency of flexibility resources on the demand-side. Partial data analysis can be performed on the electric meter side without uploading data involving user privacy, and thus high user acceptance is achieved. The model stored in the electric meter has low requirements on the memory, computing and communication resources of the electric meter, which reduces the cost of the electric meter and the electric power data analysis system. The configuration of the electric power data analysis model between the electric meter and the edge server can improve the accuracy of the electric power data analysis model and reduce the training time.

### BRIEF DESCRIPTION OF DRAWINGS

The foregoing and other aspects, features, and advantages of specific embodiments of the present disclosure are made more apparent from the following description in conjunction with the accompanying drawings, in which:

FIG. 1 shows a flowchart of a method performed by an electric meter according to an embodiment of the present disclosure;

FIG. 2 shows a schematic diagram illustrating a training process and timeline of an electric power data analysis model according to an embodiment of the present disclosure;

FIG. 3 shows a schematic diagram of a system for electric power data analysis according to an embodiment of the present disclosure;

FIG. 4 shows a physical schematic diagram of a system for electric power data analysis according to an embodiment of the present disclosure;

FIG. 5 shows a schematic diagram of an electric meter according to an embodiment of the present disclosure; and

FIG. 6 shows a schematic diagram of an edge server according to an embodiment of the present disclosure.

### DETAILED DESCRIPTION OF THE INVENTION

Before proceeding with the following detailed description, it may be helpful

to set forth definitions of certain terms and phrases used throughout the present disclosure. The terms “include” and “comprises” and their derivatives mean including but not limited to. The phrase “at least one”, when used with a list of items, means that different combinations of one or more of the listed items may be used, and only one item in the list may be required. For example, “at least one of A, B, C” includes any of the following combinations: “A, B, C,” “A and B,” “A and C,” “B and C,” “A and B and C.”

Definitions of other specific words and phrases are provided throughout the present disclosure. It should be understood by a person of ordinary skill in the art that, in many cases, if not most cases, such definitions also apply to previous and future uses of such defined words and phrases.

In the present patent application document, the various embodiments of the principles of the present disclosure described below in conjunction with the accompanying drawings are for illustration only and should not be interpreted in any way as limiting the scope of the present disclosure. Those skilled in the art will understand that the principles of the present disclosure can be implemented in any appropriately arranged system or device. In some cases, the actions described in the present disclosure can be performed in a different order and still achieve the desired result. Furthermore, the processes depicted in the accompanying drawings do not necessarily require the specific order or sequential order shown to achieve the desired result. In certain embodiment, multitasking and parallel processing may be advantageous.

The text and drawings are provided as examples only to aid in understanding the present disclosure. They should not be interpreted as limiting the scope of the claims appended to the present disclosure in any way. Throughout the drawings, the same reference numerals generally indicate the same elements. Although certain embodiments and examples have been provided, it is clear to those skilled in the art based on the contents of the present disclosure that changes may be made to the embodiments and examples shown without departing from the scope of the present disclosure.

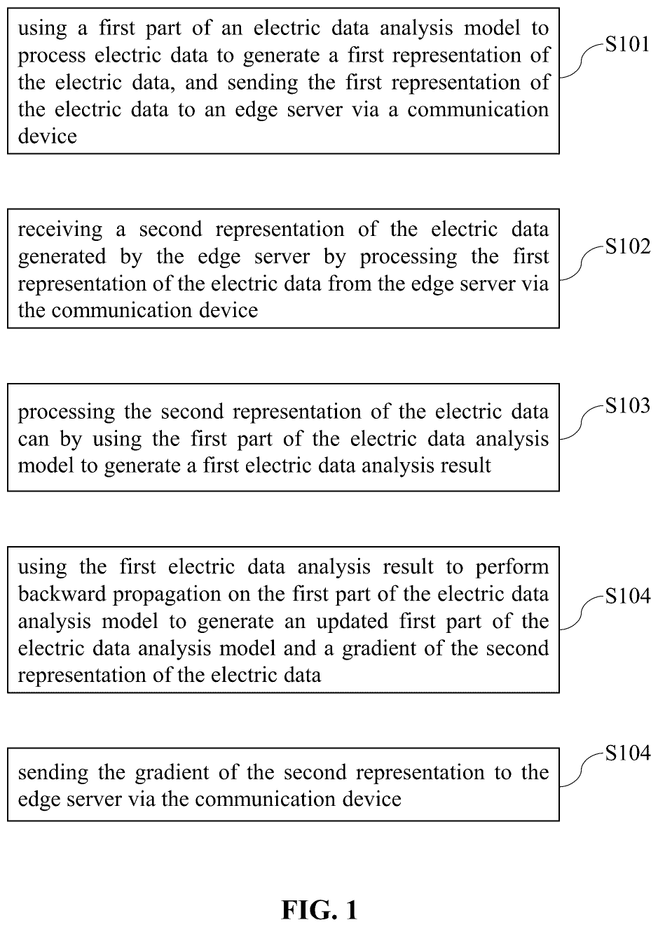

FIG. 1 shows a flowchart of a method performed by an electric meter according to an embodiment of the present disclosure.

At S101, a first part of an electric data analysis model can be used to process electric data to generate a first representation of the electric data, and the first representation of the electric data is sent to an edge server via a communication device.

At S102, a second representation of the electric data generated by the edge server by processing the first representation of the electric data can be received from the edge server via the communication device.

At S103, the second representation of the electric data can be processed using the first part of the electric data analysis model to generate a first electric data analysis result.

At S104, the first electric data analysis result can be used to perform backward propagation on the first part of the electric data analysis model to generate an updated first part of the electric data analysis model and a gradient of the second representation of the electric data.

At S105, the gradient of the second representation can be sent to the edge server via the communication device.

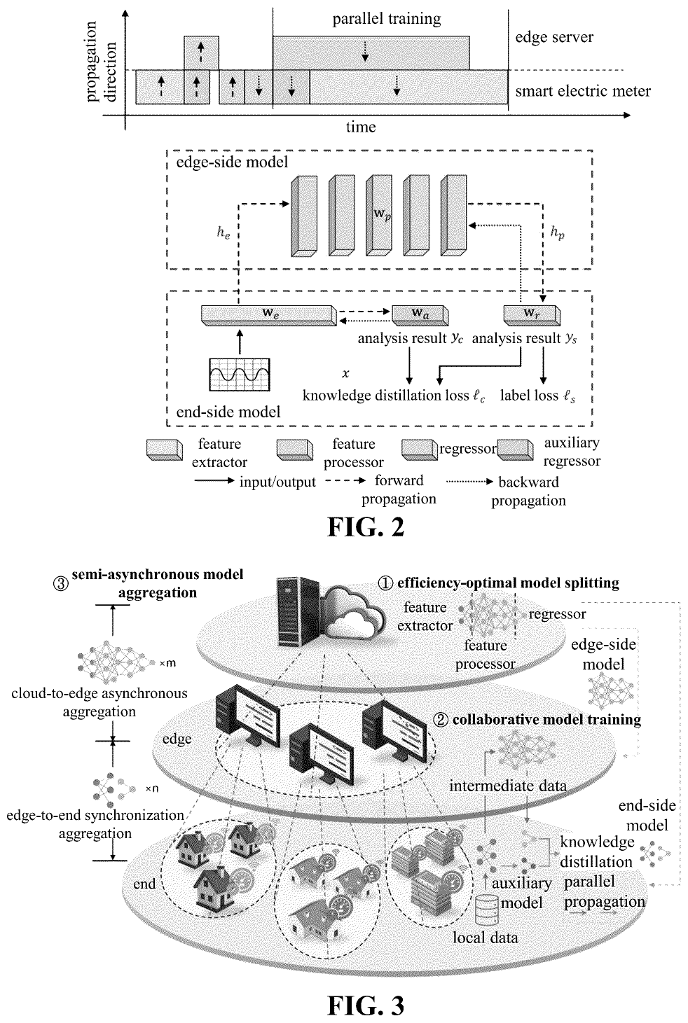

FIG. 2 shows a schematic diagram illustrating a training process and timeline of an electric power data analysis model according to an embodiment of the present disclosure.

As shown in FIG. 2, an electric power data analysis model w can be distributed in the edge server and the electric meter. For example, the electric power data analysis model w can be distributed in the edge server and the electric meter using a method such as federated splitting. For example, a first part of the electric power data analysis model can be set in the electric meter. The first part of the electric power data analysis model includes a feature extractor wₑ and a regressor wₐ. For example, a second part of the electric power data analysis model can be set in the edge server. The second part of the electric power data analysis model includes a feature processor wₚ. The electric power data analysis model may further include an auxiliary regressor wₐ set in the electric meter. By this way, the electric power data analysis model can be divided into two trainable models; that is, the main model is wₛ=[wₑ, wₚ, wᵣ] and the auxiliary model is w_{c}=[wₑ, wₐ].

The electric power data can be processed using the first part of the electric power data analysis model to generate the first representation of the electric power data, and the first representation of the electric power data can be sent to the edge server via the communication device. For example, the electric power data can be processed using the feature extractor wₑ to generate the first representation of the electric power data. In one embodiment, the electric meter first uses historical data x as input and then obtains the extracted first representation hₑ=f(wₑ, x).

The first representation of the electric power data can be processed by the edge server using the second part of the electric power data analysis model to generate the second representation. For example, the feature processor wₚ in the edge server can further extract the representation hₚ=f(wₚ, hₑ).

The second representation of the electric power data generated by the edge server by processing the first representation of the electric power data is received from the edge server via the communication device. The second representation of the electric power data can be processed using the first part of the electric power data analysis model to generate a first electric power data analysis result. The second representation of the electric power data can be processed using the regressor wₐ to generate the first electric power data analysis result. For example, the electric meter uses the regressor wₐ to obtain the predicted value yₛ=f(wᵣ, hₚ) of the main model.

The first electric power data analysis result can be used to perform backward propagation on the first part of the electric power data analysis model to generate the updated first part of the electric power data analysis model and the gradient of the second representation of the electric power data. The gradient of the second representation can be sent to the edge server via the communication device. The auxiliary regressor wₐ is configured to process the first representation of the electric power data to generate a second electric power data analysis result. For example, the electric meter can directly calculate a predicted value of a local auxiliary model; that is, y_{c}=f(wₐ, hₑ). For example, in addition to a main model loss function [symbol] ₛ, an introduced auxiliary model (e.g., auxiliary regressor wₐ) also generates an additional loss function [symbol] _{c}.

The proposed method has two outstanding advantages. First, the gradient calculation of wₑ is independent of the backward propagation progress of wₚ. In other words, the edge server does not need to send the returned gradient further to the electric meter, which can save a quarter of the communication overhead. Second, the backward propagation performed on the first part of the electric power data analysis model and the backward propagation performed on the second part of the electric power data analysis model can be performed in parallel (as shown in the timeline diagram at the top of FIG. 2). This configuration can reduce the computation time required for backward propagation (which is the majority time cost of computation in model training) by half.

The backward propagation can be performed on the regressor wᵣ based on

the first loss between the first electric power data analysis result and the true value (e.g., the main model loss [symbol] ₛ(wₛ)). The backward propagation can be performed on the feature extractor wₑ based on the second loss between the second electric power data analysis result and the true value (e.g., the additional loss [symbol] _{c}(w_{c}) of the auxiliary model). In order to achieve accurate data analysis, it is necessary to find the optimal parameters. The backward propagation performed on the feature extractor further includes: performing backward propagation on the feature extractor wₑ based on the second loss and the knowledge distillation loss between the first electric power data analysis result and the second electric power data analysis result. For example, the process of minimizing the main model loss [symbol] ₛ(wₛ) and the additional loss [symbol] _{c}(w_{c}) of the auxiliary model on a data set |D| of training data for one training round can be expressed by Equations (1) and (2):

$${min}_{{w}_{r} , {w}_{p}} {ℒ}_{s} ( {w}_{s} ) = {min}_{{w}_{r} , {w}_{p}} \frac{1}{\vert D \vert} {\sum }_{x ∈ D} {ℓ}_{s} ( {w}_{s ,} x ) \qquad ( 1 )$$

$${min}_{{w}_{a} , {w}_{e}} {ℒ}_{s} ( {w}_{c} ) = {min}_{{w}_{a} , {w}_{e}} \frac{1}{\vert D \vert} {\sum }_{x ∈ D} {ℓ}_{c} ( {w}_{c ,} x ) \qquad ( 2 )$$

As a shared layer of the main model wₛ and the auxiliary model w_{c}, the updating by the feature extractor wₑ can affect the results of [symbol] ₛ and [symbol] _{c}. Therefore, the parameter optimization of wₑ is expected to minimize the target loss of the optimization problem. However, wₑ is only used as a decision variable in the second optimization problem. In other words, wₑ is optimized according to the loss [symbol] _{c} in the second optimization problem and it is independent on the loss [symbol] ₛ in the first optimization problem. This lack of correlation may cause the converged optimal solution of wₑ in the second optimization problem to produce considerable losses in the first optimization problem. The loss function can be redesigned by incorporating knowledge distillation to introduce the convergence of the first optimization problem (e.g., Equation (1)) as an objective into the optimization of wₑ. The specific expressions of [symbol] ₛ and [symbol] _{c} are shown in Equations (3) and (4) below:

$${ℓ}_{s} ( {w}_{s} , x ) = ℓ ( y , {y}_{s} ) \qquad ( 3 )$$

$${ℓ}_{c} ( {w}_{c} , x ) = μℓ ( y , {y}_{c} ) + {\underbrace{γℓ ( {y}_{s} , {y}_{c} )}}_{knowledge distillation} \qquad ( 4 )$$

where, y represents the true label, μ and γ represent the weights of the label loss and the knowledge distillation loss, respectively. Here, [symbol] is the basic loss function, which can be L2 loss for regression tasks and can be cross entropy loss function for classification tasks, but the present disclosure is not limited thereto. The knowledge distillation method can be applied to making the prediction result of w_{c} closer to the prediction result of wₛ.

In addition, since the prediction outputs yₛ and y_{c} can be obtained from the main model and the auxiliary model respectively, the method according to embodiments of the present disclosure shows strong adaptability to different communication conditions in the reasoning stage. When the communication network is working normally, since the main model has more hidden layers and usually has the better performance than the auxiliary model, yₛ is given priority as the analysis result. In order to further improve the robustness of the prediction, the first electric power data analysis result can be integrated with the second electric power data analysis result. For example, the prediction results of the main model and the auxiliary model are integrated with each other.

The first electric power data analysis result is output when the communication capability exceeds a threshold, and the second electric power data analysis result is output when the communication capability falls below the threshold. For example, when the communication network is not smooth, which hinders the parameter transmission of the main model, the electric meter can still perform data analysis according to the local auxiliary model, and the auxiliary model can obtain the analysis result y_{c} without communication.

In view of the memory constraints of the electric meter, the majority of the resource burden required for storing and training the electric power data analysis model w needs to be transferred from the electric meter to the edge server. In addition, in order to ensure user privacy and enhance user acceptance, the feature extractor wₑ and regressor wᵣ involving privacy raw data can be deployed on the electric meter, and the feature processor wₚ requiring complex calculations can be deployed on the edge server. “α” can be defined as a split ratio of the number of model parameters deployed on the electric meter to the number of parameters of the entire model; that is, (|wₑ|+|wᵣ|)/|w|. When splitting the electric power data analysis model w, the goal is to determine an optimal split ratio a that can minimize the training time T of the entire electric power data analysis model w within the memory constraint Mₛₘ of the electric meter. This process can be expressed by Equation (5) below.

$$\begin{matrix}{min}_{{α}^{*}} T ( α ) \\ s . t . M ( α ) \leq {M}_{sm}\end{matrix} \qquad ( 5 )$$

A peak memory usage M(α) during the training the electric power data analysis model w on the electric meter consists of three main components, including model memory, intermediate memory, and optimizer memory, as detailed below:

For the i-th layer of the neural network included in the electric power data analysis model w: First, the model memory refers to the memory space allocated to store the basic network parameters wᵢ; that is, the weights and biases of each layer of the network. Among them, some non-parametric layers (e.g., activation layers) do not cause model memory overhead. In addition, the intermediate memory includes two parts: memory usage required for output aᵢ of neurons in each layer during forward propagation, and memory usage required for gradients corresponding to the output aᵢ of neurons in each layer and the basic network parameters wᵢ during backward propagation. Finally, the optimizer memory refers to the memory usage used to store state variables for the optimizer. For example, a standard SGD optimizer needs to cache momentum value of wᵢ, while an Adam optimizer needs to cache first and second momentum values of wᵢ. Generally speaking, all parameters of the electric meter are statically allocated memory and stored as single-precision floating-point numbers. Taking an electric power data analysis model w using the Adam optimizer and including a total of L neural network layers as an example, once the total number of the parameters per layer of the model on the electric meter side is determined, the peak memory usage M(α) can be computed by multiplying these parameters by a 32-bit floating-point value. Specifically, this process is expressed in Equation (6) below.

$$M ( α ) = 32 \times {\sum }_{i = 1}^{⌊ α L ⌋} ( \vert B \vert ( \vert {w}_{i} \vert + 2 \vert {a}_{i} \vert ) + 3 \vert {w}_{i} \vert ) \qquad ( 6 )$$

where, [αL] represents the maximum number of the layers of the model on the electric meter side, whose network parameters do not exceed α of the entire model; B represents a batch size of a training iteration.

The time consumed in training the electric power data analysis model

includes the time for performing forward propagation and backward propagation on the electric power data analysis model and the time for the processor to communicate with the edge server via the communication device. For example, the training time of the electric power data analysis model may include computing time and communication time. It is assumed that the collaborative environment includes an edge server and K electric meters. Pₛₘ, Pₑₛ, and R represent the computational capability of the electric meter, the computational capability of the edge server, and the communication transmission rate between the electric meter and the edge server, respectively. For simplicity, it is assumed that the dataset size of the training data of each electric meter per training round is |D| and that each neural network layer contains the same number of neurons, denoted as s.

First, the time required for computation during the forward propagation and backward propagation is analyzed. The time for performing the forward propagation and the backward propagation on the electric power data analysis model may include the time for performing the forward propagation on the first part of the electric power data analysis model in the electric meter, the time for performing the forward propagation on the second part of the electric power data analysis model in the edge server, the time for performing the backward propagation on the first part of the electric power data analysis model in the electric meter, and the sum of the maximum values of the time for performing the backward propagation on the second part of the electric power data analysis model in the edge server. It is assumed that the amount of the computation required for each parameter is equal/the same, denoted as n. In memory analysis, |w| is usually much larger than |a|, so for the entire data set, the computational complexity of the entire model training can be expressed as [symbol] (|D∥w|). Therefore, the amount of the computation per training round can be expressed as n|D∥w|. A parameter B is used to represent the ratio of the forward propagation computation to the overall training computation of the electric power data analysis model w. Initially, the electric meter can perform forward propagation on its local model, which takes time

$$\frac{αβ n \vert D \vert \vert w \vert}{{P}_{sm}} .$$

Then, the edge server can perform forward propagation on the edge side model of each electric meter, which takes time

$$\frac{( 1 - α ) β n \vert D \vert \vert w \vert K}{{P}_{es}} .$$

Afterwards, the electric meter and the edge server can parallelly perform backward propagation on the first and second parts of the electric power data analysis model w deployed therein, respectively. The time of parallel propagation is determined by the maximum value of the time required for the processing by the electric meter and the time required for the processing by the model in the edge server, which can be expressed as

$$max \{ \frac{α ( 1 - β ) n \vert D \vert \vert w \vert}{{P}_{sm}} , \frac{( 1 - α ) ( 1 - β ) n \vert D \vert \vert w \vert K}{{P}_{es}} \} .$$

The time required for communication may include the time for the electric meter to send the first representation of the electric power data to the edge server, the time for the electric meter to receive the second representation of the electric power data from the edge server, the time for the electric meter to send the gradient of the second representation of the electric power data to the edge server, the time for the electric meter to receive the first part of the electric power data analysis model from the edge server, and the time for the electric meter to send the updated first part of the electric power data analysis model to the edge server. The electric meter can send the updated first part of the electric power data analysis model to the edge server. The electric meter can receive the first part of the electric power data analysis model (e.g., the aggregated part) from the edge server and store the first part of the electric power data analysis model in the memory. For example, in each training round, the electric meter needs to communicate with the edge server to upload and download the weights of the model on the electric meter side, and each process for it requires a time of

$$\frac{α \vert w \vert}{R} .$$

In each training round, multiple batches for training can be performed on the electric power data analysis model w. Since the electric power data analysis model w is deployed in the electric meter and the edge server respectively, the intermediate activation of the neural network layer (e.g., the first representation and the second representation of the electric power data) needs to be transmitted twice between the electric meter and the edge server for forward propagation, which takes time

$$\frac{2 s \vert D \vert}{R}$$

as required. The edge server no longer returns the gradient of the neural network layer to the electric meter. The electric meter can send the gradient of the activation of the neural network layer (e.g., the gradient of the second representation of the electric power data) back to the edge server, which takes time

$$\frac{s \vert D \vert}{R}$$

as required.

Therefore, the total training time T(α) used per training round can be expressed as Equation (7):

$$T ( α ) = \frac{3 s \vert D \vert + 2 α \vert w \vert}{R} + \frac{αβ n \vert D \vert \vert w \vert}{{P}_{sm}} + \frac{( 1 - α ) β n \vert D \vert \vert w \vert K}{{P}_{es}} + max \{ \frac{α ( 1 - β ) n \vert D \vert \vert w \vert}{{P}_{sm}} , \frac{( 1 - α ) ( 1 - β ) n \vert D \vert \vert w \vert K}{{P}_{es}} \} \qquad ( 7 )$$

The ratio of the size of the first part of the electric power data analysis model to the size of the electric power data analysis model can be determined based on the time consumed to train the electric power data analysis model. For example, the optimal split ratio can be obtained based on the overall training time T(α).

The upper bound of the size of the first part of the electric power data analysis model can be less than or equal to that the available storage capacity of the memory of the electric meter minus the size of the intermediate memory of the first part of the electric power data analysis model and the size of the optimizer memory of the first part of the electric power data analysis model. In this regard, the memory usage of the auxiliary regressor is very small and can be ignored. The upper bound αᵤₚₚₑᵣ of the split ratio can be computed to ensure that the peak memory usage M(α) is within the range of the memory constraint Mₛₘ. The upper bound can be expressed as Equation (8):

$${α}_{upper} = inf \{ α : M ( α ) \leq {M}_{sm} \} \qquad ( 8 )$$

The lower bound of the size of the first part of the electric power data analysis model can be greater than or equal to the size of the input layer and the output layer of the electric power data analysis model. For example, in order to ensure the privacy of user data, at least the input layer and the output layer (i.e., the first layer and the last layer) of the electric power data analysis model need to be deployed on the electric meter. Therefore, the lower bound of the split ratio α_{lower} can be computed, which can be expressed as Equation (9):

$${α}_{lower} = \frac{\vert {w}_{1} \vert + \vert {w}_{L} \vert}{\vert w \vert} \qquad ( 9 )$$

Building upon this, the aforementioned optimization process for the split ratio can be addressed through a piecewise analysis. The ratio of the size of the first part of the electric power data analysis model to the size of the electric power data analysis model can be determined (e.g., a split ratio) based on the lower bound and the upper bound of the size of the first part of the electric power data analysis model, so that the time consumed in the training the electric power data analysis model gets minimized. The determined efficiency-optimal split ratio α* (i.e., the shortest overall training time T(α)) can be expressed as:

$$If {P}_{es} > {K ( \frac{1}{nR \vert D \vert} + \frac{β}{{P}_{sm}} )}^{- 1} , then {α}^{*} = {α}_{upper} ;$$

$$If {P}_{es} < β {K ( \frac{2}{nR \vert D \vert} + \frac{1}{{P}_{sm}} )}^{- 1} , then {α}^{*} = {α}_{lower} ;$$

$$If β {K ( \frac{2}{nR \vert D \vert} + \frac{1}{{P}_{sm}} )}^{- 1} \leq {P}_{es} \leq {K ( \frac{1}{nR \vert D \vert} + \frac{β}{{P}_{sm}} )}^{- 1} , then :$$

$${α}^{*} = \{ \begin{matrix}{α}_{upper} & if {( \frac{{P}_{es}}{{KP}_{sm}} + 1 )}^{- 1} \geq {α}_{upper} \\ {( \frac{{P}_{es}}{{KP}_{sm}} + 1 )}^{- 1} & if {α}_{upper} \leq {( \frac{{P}_{es}}{{KP}_{sm}} + 1 )}^{- 1} \leq {α}_{lower} \\ {α}_{lower} & if {( \frac{{P}_{es}}{{KP}_{sm}} + 1 )}^{- 1} \leq {α}_{lower}\end{matrix}$$

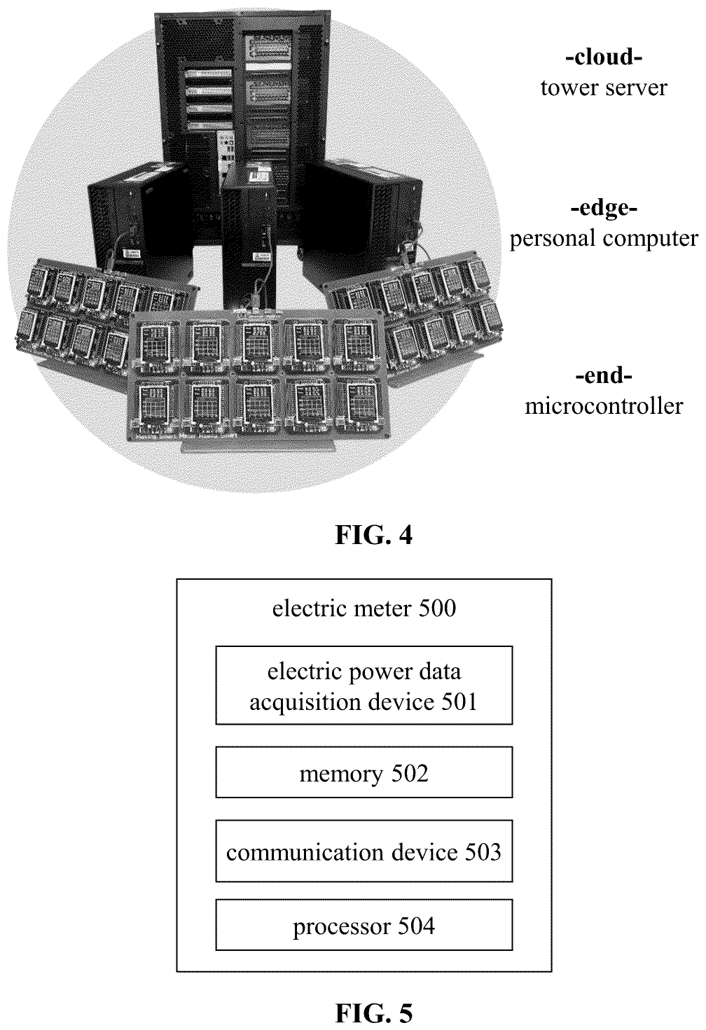

FIG. 3 shows a schematic diagram of a system for electric power data analysis according to an embodiment of the present disclosure. FIG. 4 shows a physical schematic diagram of a system for electric power data analysis according to an embodiment of the present disclosure.

As shown in FIG. 3, the system for electric power data analysis can perform semi-asynchronous model aggregation.

To leverage the large volume of data from distributed electric meters for training a global model, the network parameters of the terminal-side (i.e., electric meter-side) models and the edge-side (i.e., edge server-side) models are jointly aggregated. Due to the heterogeneity of the computational capability and communication rate of the electric meters, the completion time of the model training may vary greatly. In this case, the two widely used aggregation methods referring to synchronous aggregation and asynchronous aggregation have their own advantages and disadvantages. The synchronous method can achieve stable global model updates, but it may cause delays due to the electric meter with the longest arrival time. The asynchronous method almost eliminates the waiting delay, but the model accuracy is low due to the stochastic gradients from individual models on the electric meter side. In order to solve this technical problem, according to embodiments of the present disclosure, the advantages of these two methods are combined to design a two-stage semi-asynchronous method, which includes end-edge synchronous model aggregation and edge-cloud asynchronous model aggregation.

According to an embodiment of the present disclosure, a system for electric power data analysis is provided. The system includes: one or more electric meters; one or more edge servers, and a cloud server. The one or more electric meters are clustered into one or more electric meter sets based on computational capabilities and communication rates of the electric meters. Each of the one or more edge servers corresponds to one of the one or more electric meter sets. The cloud server corresponds to the one or more edge servers. The one or more electric meters are configured to train a first part of an electric power data analysis model, in which the training includes: using the first part of the electric power data analysis model to process electric power data to generate a first representation of the electric power data; sending the first representation of the electric power data to the edge server via a communication device; receiving, from the edge server via the communication device, a second representation of the electric power data generated by the edge server by processing the first representation of the electric power data; using the first part of the electric power data analysis model to process the second representation of the electric power data to generate a first electric power data analysis result; performing backward propagation on the first part of the electric power data analysis model using the first electric power data analysis result to generate an updated first part of the electric power data analysis model and a gradient of the second representation of the electric power data; and sending the gradient of the second representation to an edge server via the communication device. A edge server of the one or more edge servers is configured to train a second part of the electric power data analysis model, in which the training includes: receiving the first representation of the electric power data from the electric meter via the communication device; processing the first representation of the electric power data using the second part of the electric power data analysis model to generate a second representation of the electric power data; sending the second representation of the electric power data to the electric meter via the communication device; receiving the gradient of the second representation from the electric meter via the communication device; and performing backward propagation on the second part of the electric power data analysis model using the gradient of the second representation to generate an updated second part of the electric power data analysis model. An edge server of the one or more edge servers synchronously aggregates the electric power data analysis model corresponding to the edge server, and the cloud server asynchronously aggregates the electric power data analysis model in the one or more edge servers corresponding to the cloud server.

In the framework shown in FIG. 3, each edge server interacts with a cluster of electric meters and aggregates their models to form an entire model. Then, a powerful cloud server interacts with all edge servers to update a final global model. In order to reduce aggregation delay of each electric meter cluster, a clustering algorithm based on hardware configuration (e.g., computational resources) can be used to assign electric meters with similar training times to the same edge server. The overall training time T is related to two hardware characteristics of the electric meters, including a computational capability Pₛₘ and a communication rate R. Therefore, K electric meters can be clustered into M clusters according to their feature vectors [Pₛₘ, R], where the number of electric meters assigned to the i-th edge server is denoted as Kᵢ. Here, a balanced K-means algorithm can be used to ensure that the number of electric meters in each cluster is relatively fair and to avoid overloading or underloading of edge servers in any cluster. After all the electric meters in the clusters complete model training, the edge servers synchronize and aggregate these models. The synchronized aggregation can be expressed by Equation (10) below:

$${w}_{( i )}^{t + 1} = \frac{1}{{K}_{i}} {\sum }_{k = 1}^{{K}_{i}} {w}_{k}^{t + 1} \qquad ( 10 )$$

where,

$${w}_{( i )}^{t + 1}$$

represents the aggregate model of the i-th edge server in round t+1, and

$${w}_{k}^{t + 1}$$

represents the partial model trained by the k-th electric meter in round t+1.

Although cluster-based end-edge synchronous aggregation greatly reduces the latency of intra-cluster aggregation, the training time among different clusters is still different. Therefore, asynchronous aggregation on the edge servers is performed on the cloud server to further reduce latency. Since assignment of the electric meters of each cluster is independent of the data distribution, the aggregated gradient of each cluster can be regarded as an unbiased estimate of the full gradient across all electric meters. Benefiting from the robustness of intra-cluster model aggregation, the method according to embodiments of the present disclosure can effectively mitigate the accuracy degradation problem encountered in asynchronous aggregation. After receiving the aggregation model from the i-th edge server, the cloud server can update the global model in an asynchronous manner. The asynchronous aggregation process can be expressed by Equation (11) below:

$${w}^{t + 1} = ( 1 - {τ}_{i} ) {w}^{t} + {τ}_{i} {w}_{( i )}^{t + 1} \qquad ( 11 )$$

where, w^{t} represents the aggregation model on the cloud server at the t-th round, and τᵢ represents the weight of

$${w}_{( i )}^{t + 1}$$

in the asynchronous update.

FIG. 5 shows a schematic diagram of an electric meter according to an embodiment of the present disclosure.

As shown in FIG. 5, the electric meter 500 includes an electric power data acquisition device 501, a memory 502, a communication device 503, and a processor 504.

The electric power data acquisition device 501 is configured to collect electric power data. The memory 502 is configured to store the first part of the electric power data analysis model. The communication device 503 can communicate with an external device (e.g., an edge server). The processor is coupled to the electric power data acquisition device, the memory, and the communication device and is configured to execute the method shown in FIG. 1.

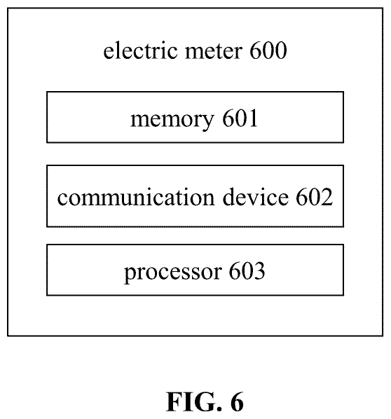

FIG. 6 shows a schematic diagram of an edge server according to an embodiment of the present disclosure.

As shown in FIG. 6, the edge server includes a memory 601, a communication device 602, and a processor 603.

The memory 601 is configured to store the second part of the electric power data analysis model. The communication device 602 can communicate with an external device (e.g., a cloud server, an electric meter, etc.). The processor 603 is coupled to the memory and the communication device and is configured to train the second part of the electric power data analysis model, in which the training may include: receiving a first representation of electric power data from an electric meter via the communication device; processing the first representation of electric power data using a second part of the electric power data analysis model to generate a second representation of the electric power data; sending the second representation of the electric power data to the electric meter via the communication device; receiving a gradient of the second representation from the electric meter via the communication device; and performing backward propagation on the second part of the electric power data analysis model using the gradient of the second representation to generate an updated second part of the electric power data analysis model.

The electric meter, the edge server, the cloud server, and the system for electric power data analysis according to the present disclosure are advantageous for improving the management efficiency of flexibility resources on the demand-side. Partial data analysis can be performed on the electric meter side without uploading data involving user privacy, and thus high user acceptance is achieved. The model stored in the electric meter has low requirements on the memory, computing and communication resources of the electric meter, which reduces the cost of the electric meter and the electric power data analysis system. The configuration of the electric power data analysis model between the electric meter and the edge server can improve the accuracy of the electric power data analysis model and reduce the training time. The electric meter, the edge server, the cloud server and the system for electric power data analysis based on federated splitting learning can analyze user electric power data in a privacy-preserving manner, improving the edge computing capabilities of large-scale deployments of smart electric meters. This is advantageous for more efficiently realizing the regulation potential of distributed flexibility resources and promoting the digital transformation and development of the power system

Although the present disclosure has been described with exemplary embodiments, various changes and modifications may be suggested to those skilled in the art. The present disclosure is intended to cover such changes and modifications that fall within the scope of the appended claims.

Any description in the present invention should not be construed as implying that any particular element, step, or function is an essential element that must be included within the scope of the claims. The scope of the subject matter of the patent application is limited only by the claims.

What is claimed is:

1. An electric meter, comprising:
an electric power data acquisition device configured to collect electric power data;
a memory configured to store a first part of an electric power data analysis model;
a communication device;
a processor coupled to the electric power data acquisition device, the memory and the communication device and configured to train the first part of the electric power data analysis model, wherein training the first part of the electric power data analysis model comprises:
processing the electric power data using the first part of the electric power data analysis model to generate a first representation of the electric power data;
sending the first representation of the electric power data to an edge server via the communication device;
receiving, from the edge server via the communication device, a second representation of the electric power data generated by the edge server by processing the first representation of the electric power data;
processing the second representation of the electric power data using the first part of the electric power data analysis model to generate a first electric power data analysis result;
performing backward propagation on the first part of the electric power data analysis model using the first electric power data analysis result to generate an updated first part of the electric power data analysis model and a gradient of the second representation of the electric power data; and
sending the gradient of the second representation to the edge server via the communication device.

2. The electric meter according to claim 1, wherein the second representation of the electric power data is generated by the edge server by processing the first representation of the electric power data using a second part of the electric power data analysis model.

3. The electric meter according to claim 1, wherein the first part of the electric data analysis model comprises a feature extractor and a regressor,
wherein processing the electric data using the first part of the electric data analysis model to generate the first representation of the electric data comprises processing the electric data using the feature extractor to generate the first representation of the electric data,
wherein processing the second representation of the electric data using the first part of the electric data analysis model to generate the first electric data analysis result comprises processing the second representation of the electric data using the regressor to generate the first electric data analysis result.

4. The electric meter according to claim 3, wherein the performing backward propagation on the first part of the electric data analysis model using the first electric data analysis result comprises performing backward propagation on the regressor based on a first loss between the first electric data analysis result and a true value.

5. The electric meter according to claim 4, wherein the memory is further configured to store an auxiliary regressor of the electric data analysis model,
wherein the auxiliary regressor is configured to process the first representation of the electric data to generate a second electric data analysis result.

6. The electric meter according to claim 5, wherein the processor is further configured to integrate the first electric data analysis result with the second electric data analysis result.

7. The electric meter according to claim 6, wherein the processor is further configured to:
output the first electric power data analysis result when a communication capability is higher than a threshold value;
output the second electric power data analysis result when the communication capability is lower than the threshold value.

8. The electric meter according to claim 5, wherein the processor is further configured to perform backward propagation on the feature extractor based on a second loss between the second electric power data analysis result and the true value.

9. The electric meter according to claim 8, wherein performing backward propagation on the feature extractor further comprises performing backward propagation on the feature extractor based on the second loss and a knowledge distillation loss between the first electric power data analysis result and the second electric power data analysis result.

10. The electric meter according to claim 8, wherein the gradient of the second representation is introduced to perform backward propagation on the second part of the electric power data analysis model,
wherein the backward propagation performed on the first part of the electric power data analysis model is performed in parallel with the backward propagation performed on the second part of the electric power data analysis model.

11. The electric meter according to claim 2, wherein a ratio of the size of the first part of the electric power data analysis model to the size of the electric power data analysis model is determined based on time consumed to train the electric power data analysis model.

12. The electric meter according to claim 11, wherein the time consumed for training the electric data analysis model comprises time for performing forward propagation and backward propagation on the electric data analysis model and time for the processor to communicate with the edge server via the communication device.

13. The electric meter according to claim 12, wherein the time for performing forward propagation and backward propagation on the electric data analysis model comprises a sum of the maximum values of time for performing forward propagation on the first part of the electric data analysis model in the electric meter, time for performing forward propagation on the second part of the electric data analysis model in the edge server, time for performing backward propagation on the first part of the electric data analysis model in the electric meter, and time for performing backward propagation on the second part of the electric data analysis model in the edge server.

14. The electric meter according to claim 12, wherein the time for the processor to communicate with the edge server via the communication device comprises a sum of items as follows:
time for the processor to send the first representation of the electric power data to the edge server via the communication device;
time for the processor to receive the second representation of the electric power data from the edge server via the communication device;
time for the processor to send the gradient of the second representation of the electric power data to the edge server via the communication device;
time for the processor to receive the first part of the electric power data analysis model from the edge server via the communication device; and
time for the processor to send the updated first part of the electric power data analysis model to the edge server via the communication device.

15. The electric meter according to claim 11,
wherein a lower bound of the size of the first part of the electric power data analysis model is greater than or equal to the size of an input layer and an output layer of the electric power data analysis model,
wherein an upper bound of the size of the first part of the electric power data analysis model is less than or equal to that an available storage capacity of the memory of the electric meter minus the size of an intermediate memory of the first part of the electric power data analysis model and the size of an optimizer memory of the first part of the electric power data analysis model.

16. The electric meter according to claim 15, wherein a ratio of the size of the first part of the electric data analysis model to the size of the electric data analysis model is determined based on the lower bound and the upper bound of the size of the first part of the electric data analysis model, such that time consumed in training the electric data analysis model is minimized.

17. The electric meter according to claim 1, wherein the processor is further configured to send the updated first part of the electric data analysis model to the edge server via the communication device.

18. The electric meter according to claim 1, wherein the processor is further configured to receive the first part of the electric data analysis model from the edge server via the communication device and store the first part of the electric data analysis model in the memory.

19. The electric meter according to claim 18, wherein the electric meter and one or more other electric meters are clustered into an electric meter set based on a computational capability and a communication rate of the electric meter;
wherein the electric meters in the electric meter set correspond to a first edge server.

20. The electric meter according to claim 19, wherein the first part of the electric data analysis model received from the first edge server via the communication device is a first part of a synchronously aggregated electric data analysis model,
wherein the first part of the synchronously aggregated electric data analysis model is generated by the first edge server by synchronously aggregating the first part of the electric data analysis model in the electric meter set.

21. The electric meter according to claim 20, wherein the first part of the electric data analysis model received from the first edge server via the communication device is a first part of an asynchronously aggregated electric data analysis model,
wherein the first part of the asynchronously aggregated electric data analysis model is received by the first edge server from the cloud server,
wherein the first part of the asynchronously aggregated electric data analysis model is generated by the cloud server by asynchronously aggregating the electric data analysis model sent by the first edge server and one or more other edge servers.

22. An edge server, comprising:
a memory configured to store a second part of an electric power data analysis model;
a communication device;
a processor coupled to the memory and the communication device and configured to train the second part of the electric power data analysis model, wherein training the second part of the electric power data analysis model comprises:
receiving a first representation of electric power data from an electric meter via the communication device;
processing the first representation of the electric power data using the second part of the electric power data analysis model to generate a second representation of the electric power data;
sending the second representation of the electric power data to the electric meter via the communication device;
receiving a gradient of the second representation from the electric meter via the communication device;
performing backward propagation on the second part of the electric power data analysis model using the gradient of the second representation to generate an updated second part of the electric power data analysis model.

23. A system for electric power data analysis, comprising:
one or more electric meters clustered into one or more electric meter sets based on computational capabilities and communication rates of the electric meters;
one or more edge servers, wherein each of the one or more edge servers corresponds to one of the one or more electric meter sets; and
a cloud server corresponding to the one or more edge servers;
wherein, the one or more electric meters are configured to train a first part of an electric power data analysis model, wherein training the first part of the electric power data analysis model comprises:
processing electric power data using the first part of the electric power data analysis model to generate a first representation of the electric power data;
sending the first representation of the electric power data to the edge server via a communication device;
receiving, from the edge server via the communication device, a second representation of the electric power data generated by the edge server by processing the first representation of the electric power data;
processing the second representation of the electric power data using the first part of the electric power data analysis model to generate a first electric power data analysis result;
performing backward propagation on the first part of the electric power data analysis model using the first electric power data analysis result to generate an updated first part of the electric power data analysis model and a gradient of the second representation of the electric power data;
sending the gradient of the second representation to the edge server via the communication device;
wherein an edge server in the one or more edge servers is configured to train a second part of the electric power data analysis model, and training the second part of the electric power data analysis model comprises:
receiving the first representation of the electric power data from the electric meter via the communication device;
processing the first representation of the electric power data using the second part of the electric power data analysis model to generate the second representation of the electric power data;
sending the second representation of the electric power data to the electric meter via the communication device;
receiving the gradient of the second representation from the electric meter via the communication device;
using the gradient of the second representation to perform backward propagation on the second part of the electric power data analysis model to generate an updated second part of the electric power data analysis model;
wherein an edge server in the one or more edge servers synchronously aggregates the electric power data analysis model corresponding to the edge server,
wherein the cloud server asynchronously aggregates the electric power data analysis model in the one or more edge servers corresponding to the cloud server.
